(19) United States
(12) Patent Application Publication
(10) Pub. No.: US 2026/0344232 A1
(43) Pub. Date: Oct. 29, 2026

(54) DISPLAY APPARATUS

(71) Applicant: LG Display Co., Ltd., Seoul (KR)

(72) Inventors: TaeHan PARK, Paju-si (KR); Seongku LEE, Paju-si (KR); Seungyeop LEE, Paju-si (KR)

(73) Assignee: LG Display Co., Ltd., Seoul (KR)

(21) Appl. No.: 19/655,223

(22) Filed: Apr. 22, 2026

(30) Foreign Application Priority Data
Apr. 29, 2025 (KR) 10-2025-0056767

(51) Int. Cl. H10K 59/131; H10K 59/121; H10K 59/122; H10K 59/123; H10K 59/80; H10K 102/10

(52) U.S. Cl. CPC H10K 59/1315; H10K 59/1213; H10K 59/122; H10K 59/123; H10K 59/80517; H10K 59/80518; H10K 2102/103

(57) ABSTRACT

A display apparatus includes a substrate having a plurality of pixels including subpixels, a thin film transistor disposed on the substrate in each subpixel of the plurality of subpixels, a pixel electrode connected to the thin film transistor, and a low-resistance wiring in contact with the pixel electrode. The low-resistance wiring partially overlaps at least a portion of the thin film transistor in a plan view. The configuration reduces resistance of a contact portion between the pixel electrode and the thin film transistor and allows the pixel electrode to directly contact the thin film transistor without a bridge electrode formed in a gate electrode layer. The arrangement may increase a light emission area and improve light efficiency while maintaining electrical connection reliability in the display apparatus.

### CROSS-REFERENCE TO RELATED APPLICATIONS

This application claims the benefit of the Korean Patent Applications No. 10-2025-0056767 filed on Apr. 29, 2025, which are hereby incorporated by reference as if fully set forth herein.

### BACKGROUND

### Technical Field

The present disclosure relates to a display apparatus displaying images.

### Description of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

The display apparatus includes a plurality of subpixels, and the plurality of subpixels include a light-emitting element layer provided in a light-emission area. The display apparatus displays an image by emitting light from the light-emitting element layer. The light-emitting element layer includes a pixel electrode. The pixel electrode extends from the light-emitting area to the circuit area and can contact a thin film transistor in the circuit area.

Meanwhile, if a resistance of the pixel electrode is high, a luminous efficiency may decrease. Therefore, various studies are being conducted to improve (or reduce) the resistance of the pixel electrode, but there is a limit to improving (or reducing) the resistance of the pixel electrode due to a process margin for the thin film transistor.

### BRIEF SUMMARY

The present disclosure describes a display pixel structure in which a low resistance wiring layer is formed in contact with a pixel electrode while partially overlapping a thin film transistor region. Instead of using a bridge electrode formed in the gate layer, the pixel electrode directly contacts the drain electrode and resistance reduction is achieved by a conductive layer formed above the electrode. This configuration removes photolithographic spacing constraints, allowing a smaller circuit region and a larger emission aperture while reducing electrode resistance.

The low resistance wiring layer is formed from oxygen reactive metals such as Ti, Ni, Zr, and Mg group materials and therefore performs both electrical conduction and oxygen absorption. By attracting oxygen from the ITO pixel electrode, oxidation at the thin film transistor contact is reduced and device lifetime is improved. In bottom emission structures the layer is placed outside the emission region to prevent optical loss, while in top emission structures it forms part of a multilayer electrode stack including transparent and reflective layers that improves light output and reduces power consumption.

Additional embodiments include a local auxiliary electrode contact that supplies a common voltage across the panel to reduce luminance variation and a stepped reflective electrode shape that increases light extraction. The structure integrates contact resistance reduction, reliability improvement, optical efficiency improvement, aperture expansion, and panel uniformity improvement without increasing pixel size.

For example, an aspect of the present disclosure is directed to providing a display apparatus in which the resistance of a pixel electrode in contact with a thin film transistor can be improved (or reduced).

An aspect of the present disclosure is directed to providing a display apparatus in which a lifespan of the thin film transistor can be improved.

An aspect of the present disclosure is directed to providing a display apparatus in which a size (or area) of a light-emission area can be expanded.

An aspect of the present disclosure is directed to providing a display apparatus capable of improving light efficiency.

An aspect of the present disclosure is directed to providing a display apparatus in which overall power consumption can be reduced due to improved light efficiency.

The problems to be solved by embodiments of the present disclosure are not limited to those mentioned above, and other problems not mentioned above will be apparent to those skilled in the art to which the technical ideas of the present disclosure belong from the following descriptions.

A display apparatus comprises a substrate including a plurality of pixels having a plurality of subpixels, a thin film transistor provided on the substrate and provided in each of the plurality of subpixels, a pixel electrode connected to the thin film transistor, and a low-resistance wiring in contact with the pixel electrode, the low-resistance wiring partially overlaps at least a portion of the thin film transistor.

The technical benefits of the present disclosure are not limited to the above-mentioned benefits, and other benefits, which are not mentioned above, can be clearly understood by those skilled in the art from the following descriptions.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one embodiment of the present disclosure.

FIG. 2 is a schematic plan view of one pixel illustrated in FIG. 1.

FIG. 3 is a schematic cross-sectional view taken along a line I-I’ illustrated in FIG. 2.

FIG. 4 is a schematic cross-sectional view of part A shown in FIG. 3, and is a drawing explaining oxygen capture of low-resistance wiring.

FIG. 5 is a schematic cross-sectional view of part B shown in FIG. 3.

FIG. 6 is a schematic plan view of a display apparatus according to a second embodiment of the present disclosure.

FIG. 7 is a schematic cross-sectional view taken along a line Ⅱ-Ⅱ’ illustrated in FIG. 6.

FIG. 8 is a schematic cross-sectional view of a display apparatus according to a third embodiment of the present disclosure.

FIG. 9 is a schematic cross-sectional view of part C illustrated in FIG. 3.

### DETAILED DESCRIPTION OF THE DISCLOSURE

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only~’ is used. The terms of a singular form may include plural forms unless referred to the contrary.

In construing an element, the element is construed as including an error range although there is no explicit description. In describing a position relationship, for example, when a position relation between two parts is described as ‘on~’, ‘over~’, ‘under~’, and ‘next~’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

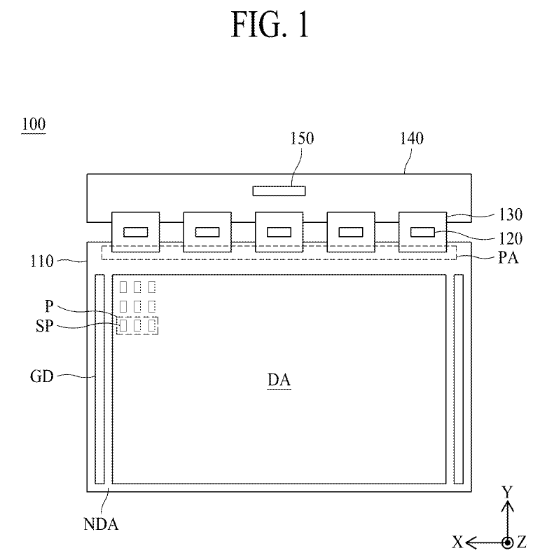

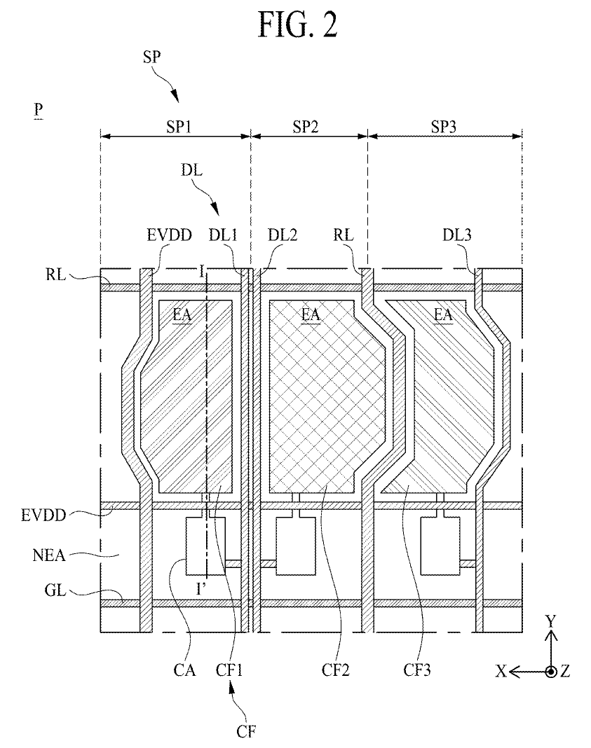

FIG. 1 is a schematic plan view of a display apparatus according to one embodiment of the present disclosure, and FIG. 2 is a schematic plan view of one pixel illustrated in FIG. 1.

Hereinafter, a first direction (Y-axis direction) represents a vertical direction based on FIG. 1, a second direction (X-axis direction) represents a horizontal direction based on FIG. 1, and a third direction (Z-axis direction) represents a thickness direction of a display apparatus 100. The first direction (Y-axis direction) may be a direction parallel to a data wiring DL (shown in FIG. 2). The second direction (X-axis direction) may be a direction parallel to a gate wiring GL (shown in FIG. 2).

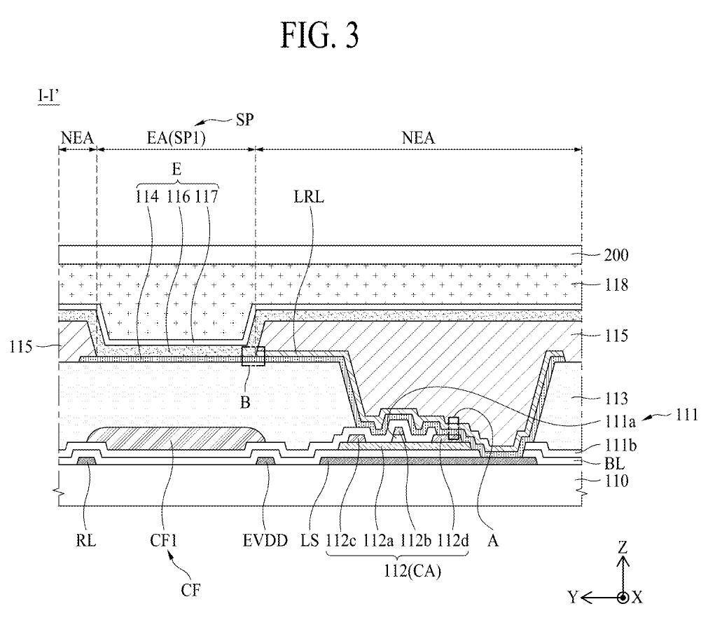

Referring to FIG. 1, a display apparatus 100 according to one embodiment of the present disclosure may include a display panel having a gate driver GD. The display panel may include a substrate 110 and an opposing substrate 200 (shown in FIG. 3) bonded to each other.

The substrate 110 according to one example may include a thin film transistor, and may be a transistor array substrate, a lower substrate, a base substrate, or a first substrate. The substrate 110 may be a transparent glass substrate or a transparent plastic substrate.

The opposing substrate 200 may be bonded to the substrate 110 via an adhesive member. For example, the opposing substrate 200 has a smaller size than the substrate 110 and can be bonded to a remaining portion except for a pad portion of the substrate 110. The opposing substrate 200 may be an upper substrate, a second substrate, or an encapsulation substrate.

Referring to FIG. 1, a display apparatus 100 according to one embodiment of the present disclosure may include a source drive integrated circuit (Hereinafter referred to as “IC”) 120, a flexible film 130, a circuit board 140, and a timing control portion 150.

The gate driver GD supplies gate signals to the gate lines in accordance with the gate control signal input from the timing controller 150. When the source drive IC 120 is manufactured as a driving chip, the source drive IC 120 may be packaged in the flexible film 130 in a chip on film COF method or a chip on plastic COP method.

Pads, such as data pads, may be formed in the non-display area of the display panel. Lines connecting the pads with the source drive IC 120 and lines connecting the pads with lines of the circuit board 140 may be formed in the flexible film 130. The flexible film 130 may be attached onto the pads by using an anisotropic conducting film, whereby the pads may be connected with the lines of the flexible film 130.

Referring again to FIG. 1, the substrate 110 according to one example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

The display area DA according to one example may include gate wirings, data wirings, pixel power wirings, and a plurality of pixels P. Each of the plurality of pixels P may include a plurality of sub-pixels SP that may be defined by gate wirings and data wirings. Each of the plurality of sub-pixels SP may be defined as the smallest unit area where actual light is emitted.

According to one example, at least three subpixels SP arranged adjacently and configured to emit different colors among a plurality of subpixels SP constitute an one unit pixel P. The one unit pixel may include, but is not limited to, a red subpixel, a green subpixel, and a blue subpixel. An one unit pixel may be configured to include at least four subpixels SP. For example, the one unit pixel may include a red subpixel, a green subpixel, a blue subpixel, and a white subpixel.

Each of the plurality of subpixels SP may include a thin film transistor and an organic light-emitting element connected to the thin film transistor. Each subpixel SP may include an organic light-emitting layer 116 (or light-emitting layer) interposed between a pixel electrode 114 (as shown in FIG. 3) and a counter electrode 117 (as shown in FIG. 3).

The organic light-emitting layer arranged in each of the plurality of subpixels SP can individually emit different color light or commonly emit white light. For example, when the organic light-emitting layer of each of the plurality of sub-pixels SP commonly emits white light, each of the red sub-pixel, the green sub-pixel, and the blue sub-pixel may include a color filter CF (or wavelength conversion member CF) that converts the white light into light of a different color. The color filter CF according to one example may include a red color filter CF1, a green color filter CF2, and a blue color filter CF3.

In a display apparatus 100 according to one embodiment of the present disclosure, an area provided with the red color filter CF1 may be a red subpixel SP1, an area provided with the green color filter CF2 may be a green subpixel SP2, an area provided with the blue color filter CF3 may be a blue subpixel SP3. In the present disclosure, the red subpixel SP1 may be represented as a first subpixel equipped to emit red light, the green subpixel SP2 may be represented as a second subpixel equipped to emit green light, and the blue subpixel SP3 may be represented as a third subpixel equipped to emit blue light.

Each of the subpixels SP supplies a predetermined current to the organic light emitting element in accordance with a data voltage of the data wiring when a gate signal is input from the gate line by using the thin film transistor. For this reason, the light emitting layer of each of the subpixels may emit light with a predetermined brightness in accordance with the predetermined current.

As shown in FIGS. 2 and 3, the display area DA may include a light emission area EA and a non-light emission area NEA. The light emission area EA is the area where light is emitted by the organic light-emitting element layer E. The non-light emission area NEA is the area that does not transmit most of the light incident from the outside.

For example, the non-light emission area NEA may be an area excluding the light emission area EA where light is emitted. In one example, the non-light emission area NEA may include a circuit area CA (shown in FIG. 3). The circuit area CA may be an area equipped with a thin film transistor 112 for driving each of the plurality of subpixels SP (or the organic light emitting element layer E of each of the plurality of subpixels SP). The organic light emitting element layer E may also be referred to as an organic light emitting element E. The circuit area CA according to one example may be arranged adjacent to the light emission area EA. The thin film transistor 112 according to one example may be provided on the substrate 110 and may be provided in each of the plurality of subpixels SP.

The display apparatus 100 according to one embodiment of the present disclosure may have a plurality of wires arranged to drive each of the plurality of pixels P. The plurality of wires according to one example may include a plurality of first signal lines and a plurality of second signal lines.

The plurality of first signal lines may extend in a second direction (X-axis direction). Each of the plurality of first signal lines may include at least one gate wire GL (or scan wire).

The plurality of second signal lines may extend in a first direction (Y-axis direction). The plurality of second signal lines may intersect the plurality of first signal lines. Each of the plurality of second signal lines may include a pixel power line EVDD, a plurality of data lines DL, and a reference line RL. The plurality of data lines DL may include a first data line DL1 for driving the first subpixel SP1, a second data line DL2 for driving the second subpixel SP2, and a third data line DL3 for driving the third subpixel SP3.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA.

The display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images.

According to one example, the pad portion PA may be placed in the non-display area NDA (or the first non-display area NDA1) above the display area DA based on FIG. 1. Since the first non-display area is formed above the display area DA, it can be expressed in terms of an upper non-display area.

The gate driver GD supplies gate signals to the gate lines in accordance with the gate control signal input from the timing controller 181. The gate driver GD may be formed on one side of the display area DA of the display panel or on the non-display area NDA outside both sides of the display area DA in a gate driver in panel GIP method as shown in FIG. 1.

The plurality of gate drivers GD may be separately disposed on a left side of the display area DA, that is, the second non-display area and a right side of the display area DA, that is, the third non-display area. Since each of the second non-display area and the third non-display area is formed on a side of the display area DA, it can be expressed in terms of side non-display areas.

According to one example, the plurality of gate drivers GD may be connected to the plurality of pixels P and the plurality of first signal lines for supplying signals to the plurality of pixels P. The plurality of first signal lines may include at least one signal line for supplying a signal for driving the pixel P.

The plurality of second signal lines may be extended in the first direction (Y-axis direction). The plurality of second signal lines may include a pixel power line EVDD and at least one data line DL to supply a data voltage to the pixel P. Each of the plurality of second signal lines may be connected to at least one of a plurality of pads, a pixel power shorting bar, and a common power shorting bar. The pixel power shorting bar and the common power shorting bar can be arranged in a fourth non-display area facing a pad portion PA based on the display area DA. Since the fourth non-display area is formed below the display area DA, it can be expressed in terms of a lower non-display area.

The pixels P are provided to overlap at least one of the first signal line or the second signal line and emit predetermined light to display an image. The light emission area EA may correspond to an area, which emits light, in the pixel P.

Referring to FIG. 3, the non-light emission area NEA may refer to an area that is provided in the display area DA and does not emit light, and may be expressed as a dead zone because it does not emit light. The dead zone according to one example may be an area in which a black matrix and/or a bank is provided, but is not limited thereto, and may refer to an area in which light is not emitted.

Hereinafter, with reference to FIG. 3, the structure of each of the plurality of sub-pixels SP will be described in detail.

Referring to FIG. 3, the display apparatus 100 according to one embodiment of the present disclosure may further include a pixel electrode 114 and a low resistance wiring LRL (also referred to as ‘a wiring LRL’).

According to one example, the pixel electrode 114 may be connected to the thin film transistor 112. For example, the pixel electrode 114 may be formed to extend from the light emission area EA to the non-light emission area NEA (or circuit area CA). Accordingly, a part of the pixel electrode 114 may be provided in the light emission area EA, and the remainder may be provided in the non-light emission area NEA. Since the pixel electrode 114 provided in the non-light emission area NEA is connected to the thin film transistor 112, the pixel electrode 114 can be electrically connected to the thin film transistor 112. According to one example, the pixel electrode 114 can be connected to a source electrode 112c or a drain electrode 112d of the thin film transistor 112.

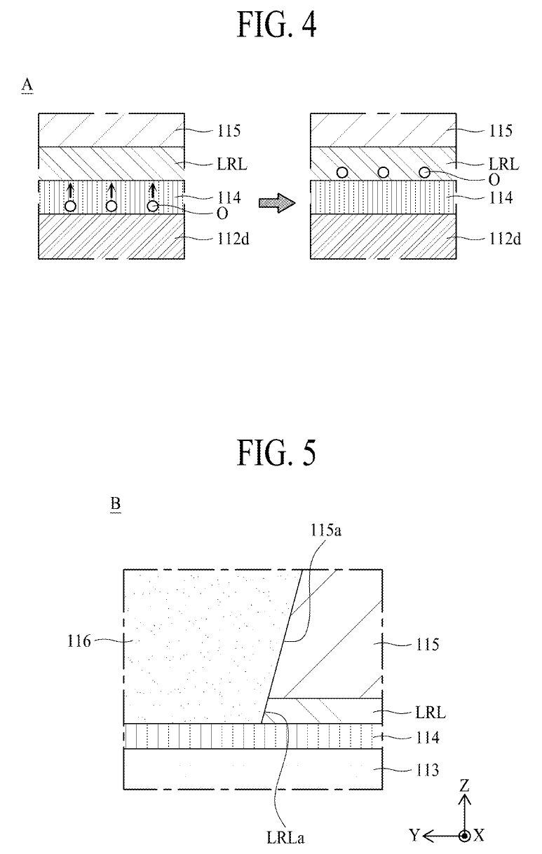

A low resistance wiring LRL according to one example may be in contact with the pixel electrode 114. For example, as shown in FIG. 3, the low resistance wiring LRL may be in contact with an upper surface of the pixel electrode 114. The low resistance wiring LRL is for improving (or reducing) the resistance of the pixel electrode 114. For example, the low resistance wiring LRL may include a metal material having a lower resistance than the pixel electrode 114. By contacting the low resistance wiring LRL with the pixel electrode 114, the overall resistance of the pixel electrode 114 can be improved (or reduced). For example, the low resistance wiring LRL can include at least one of Ti, Ni, Zr, Ba, Sr, Ca, and Mg. Ti, Ni, Zr, Ba, Sr, Ca, and Mg can be metal materials having lower resistance than the pixel electrode 114 and can also be metal materials that capture oxygen. This will be described in conjunction with FIG. 4.

As used herein, the term “low resistance wiring” or “low resistance wiring layer” refers to a conductive layer disposed in contact with a pixel electrode and having an electrical resistance lower than that of the pixel electrode material to which it is electrically connected (in other words, this term expresses a relative electrical relationship with respect to the pixel electrode). The low resistance wiring is not limited to a particular resistivity value and is defined relative to the resistance of the pixel electrode rather than by an absolute resistance. The low resistance wiring may include a metal or conductive material having a lower resistivity than a transparent conductive oxide forming the pixel electrode, and may include, for example, at least one of Ti, Ni, Zr, Ba, Sr, Ca, or Mg, alloys thereof, or other conductive materials exhibiting lower resistance than the pixel electrode. The low resistance wiring may be formed as a single layer or a multilayer and may partially overlap a thin film transistor region while contacting the pixel electrode.

According to one example, the low resistance wiring LRL may partially overlap at least a portion of the thin film transistor 112. For example, as shown in FIG. 3, the low resistance wiring LRL may be disposed on the upper surface of the pixel electrode 114 overlapping the non-light emission area NEA (or the thin film transistor 112), thereby partially overlapping the thin film transistor 112.

As illustrated in FIG. 3, the low resistance wiring LRL can reduce the resistance of the contact portion where the pixel electrode 114 and the thin film transistor 112 come into direct contact with the upper surface of the pixel electrode 114 which is partially in contact with the thin film transistor 112.

Consequently, the display apparatus 100 according to one embodiment of the present disclosure is provided such that the low resistance wiring LRL is in contact with the pixel electrode 114 that is in contact (or connected) with the thin film transistor 112, so that the resistance of the pixel electrode 114 can be improved (or reduced). Therefore, as shown in FIG. 3, the display apparatus 100 according to one embodiment of the present disclosure may have a structural feature in which a part of the low resistance wiring LRL overlaps with the pixel electrode 114 that is in contact with the source electrode 112c or the drain electrode 112d.

Referring back to FIG. 3, the display apparatus 100 according to one embodiment of the present disclosure can include a buffer layer BL, a plurality of inorganic films 111, a thin film transistor 112, a color filter CF, a planarization layer 113, a pixel electrode 114, a bank 115, an organic light emitting layer 116, a counter electrode 117, and an encapsulation layer 118.

Each of the subpixels SP according to one embodiment may include the plurality of inorganic films 111 provided on an upper surface of the buffer layer BL, including a gate insulating layer 111a, and a passivation layer 111b.

Also, each of the subpixels SP may include a color filter CF provided on the plurality of inorganic films 111, a planarization layer 113 provided on the color filter CF. The pixel electrode 114 may be disposed on the planarization layer 113.

Each of the subpixels SP may further include a bank 115 partially covering the pixel electrode 114 (or a bank 115 covering an edge of the pixel electrode 114, an organic light-emitting layer 116 covering the pixel electrode 114 and the bank 115, and a counter electrode 117 on the organic light-emitting layer 116. An encapsulation layer 118 may be disposed on the counter electrode 117.

The thin film transistor 112 for driving of subpixel SP may be arranged on the plurality of inorganic films 111. The plurality of inorganic films 111 may also be expressed in terms of a circuit element layer.

The buffer layer BL may be included in the plurality of inorganic films 111 together with the gate insulating layer 111a, and the passivation layer 111b. The pixel electrode 114, the organic light emitting layer 116 and the counter electrode 117 may be included in a light emitting element layer E.

The buffer layer BL may be formed between the substrate 110 and the gate insulating layer 111a to protect the thin film transistor 112 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor 112.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area CA of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape only on the channel area of the active layer 112a or may be formed on the entire front surface of the substrate 110 or buffer layer BL including the active layer 112a.

The gate electrode 112b may be formed on the gate insulating layer 111a to overlap the channel area of the active layer 112a. According to one example, the gate electrode 112b may be placed between the source electrode 112c and the drain electrode 112d.

The source electrode 112c may overlap with the source region of the active layer 112a. The source electrode 112c may be electrically connected to the source region of the active layer 112a.

The drain electrode 112d may be positioned spaced apart from the source electrode 112c. The drain electrode 112d may overlap with the drain region of the active layer 112a. The drain electrode 112d may be electrically connected to the drain region of the active layer 112a.

The drain electrode 112d and the source electrode 112c may be made of the same metal material. For example, each of the drain electrode 112d and the source electrode 112c may be made of IZO (Indium Zinc Oxide).

Additionally, the thin film transistor provided in the pixel area may have a characteristic in which the threshold voltage is shifted by light. To prevent this, a display panel or substrate 110 may further include a light-shielding layer LS provided below the active layer 112a of the thin film transistor 112.

The light-shielding layer LS is provided between the substrate 110 and the active layer 112a to block light incident on the active layer 112a through the substrate 110, thereby minimizing changes in the threshold voltage of the transistor caused by external light. In addition, the light shielding layer LS may be provided between the substrate 110 and the active layer 112a to prevent the thin film transistor from being visible to the user.

The passivation layer 111b may be provided on the substrate 110 to cover the pixel area. The passivation layer 111b covers a drain electrode 112d, a source electrode 112c and a gate electrode 112b of the thin film transistor 112, and the buffer layer BL.

The color filter CF may be placed on the passivation layer 111b. For example, the color filter CF may be placed between the plurality of inorganic films 111 and the planarization layer 113. The color filter CF may include a red color filter CF1 arranged in the red subpixel SP1, a green color filter CF2 arranged in the green subpixel SP2, and a blue color filter arranged in the blue subpixel SP3.

The planarization layer 113 may be provided on the substrate 110 to cover the passivation layer 111b and the color filter CF. According to one example, the planarization layer 113 may be placed between the substrate 110 and the pixel electrode 114. The planarization layer 113 may be formed in the entire circuit area CA in which the thin film transistor 112 is disposed and the entire light emission area EA. In addition, the planarization layer 113 may be formed in the other non-display area NDA except a pad area PA of the non-display area NDA and the entire display area DA. For example, the planarization layer 113 may include an extension portion (or an enlarged portion) extended or enlarged from the display area DA to the other non-display area NDA except the pad area PA. Therefore, the planarization layer 113 may have a size relatively wider than that of the display area DA.

The planarization layer 113 according to one example may be formed to have a relatively thick thickness, thereby providing a flat surface on the display area DA and the non-display area NDA. For example, the planarization layer 113 may be made of an organic material such as photo acryl, benzocyclobutene, polyimide and fluorine resin.

Referring to FIG. 3, an upper surface of the planarization layer 113 can be provided flat. Accordingly, the pixel electrode 114 on the planarization layer 113 can also be provided flat, and the organic light-emitting layer 116 and the counter electrode 117 formed thereon can also be provided in a flat form. Since the pixel electrode 114, the organic light-emitting layer 116, and the counter electrode 117, i.e., the organic light-emitting element layer E, are provided flatly in the light-emission area EA, a thicknesses of the pixel electrode 114, the organic light-emitting layer 116, and the counter electrode 117 can be formed uniformly within the light-emission area EA. Accordingly, the organic light-emitting layer 116 can emit light uniformly without deviation within the light-emission area EA.

The pixel electrode 114 may be formed on the planarization layer 113. As shown in FIG. 3, the pixel electrode 114 may be connected to the drain electrode or source electrode of the thin film transistor through a contact hole penetrating the planarization layer 113 and the passivation layer 111b. An edge portions on both sides of the pixel electrode 114 may be covered by the bank 115.

The pixel electrode 114 may be made of at least one of a transparent metal material or a semi-transmissive metal material.

Because the display apparatus 100 according to an embodiment of the present disclosure is configured as the bottom emission type, the pixel electrode 114 may be formed of a transparent conductive material (or TCO), such as indium tin oxide (ITO) capable of transmitting light. The pixel electrode 114 may be an anode electrode.

The bank 115 may be an area, which does not emit light, and can be placed adjacent to the light emission area EA of each of the plurality of sub-pixels SP. The bank 115 may be formed to cover a portion where the edge of the pixel electrode 114. Accordingly, the bank 115 may prevent the pixel electrode 114 and the counter electrode 117 in the edge of the pixel electrode 114. As illustrated in FIG. 3, the bank 115 may be provided to cover the low-resistance wiring LRL formed on the upper surface of the pixel electrode 114. In this case, the bank 115 may prevent the low-resistance wiring LRL and the counter electrode 117 from coming into contact in the non-light emission area NEA. The exposed portion of the pixel electrode 114 that is not covered by the bank 115 may be included in the light emitting portion (or light emission area EA).

After the bank 115 is formed, an organic light emitting layer 116 may be formed to cover the pixel electrode 114 and the bank 115. Accordingly, the bank 115 may be partially provided between the pixel electrode 114 and the organic light-emitting layer 116, and between the low-resistance wiring LRL and the organic light-emitting layer 116. The bank 115 can be expressed in terms of a pixel definition films. The bank 115 according to one example may comprise organic material and/or inorganic material.

The organic light emitting layer 116 may be formed on the pixel electrode 114 and the bank 115. The organic light emitting layer 116 can be placed under the counter electrode 117. According to one example, the organic light emitting layer 116 may be disposed in the light emission area EA and the non-light emission area NEA. The organic light emitting layer 116 may be provided between the pixel electrode 114 and the counter electrode 117. Thus, when a voltage is applied to each of the pixel electrode 114 and the counter electrode 117, an electric field is formed between the pixel electrode 114 and the counter electrode 117. Therefore, the organic light emitting layer 116 may emit light. The organic light emitting layer 116 may be formed of a plurality of subpixels SP and a common layer provided on the bank 115.

The organic light emitting layer 116 according to one embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The counter electrode 117 may be formed on the organic light emitting layer 116. The counter electrode 117 may be arranged in the non-display area NDA (or a part of the non-display area NDA) and the display area DA. In the display area DA, the counter electrode 117 may be arranged in the light emission area EA and the non-light emission area NEA. That is, the counter electrode 117 may be arranged to cover the entire display area DA. The counter electrode 117 may be arranged to have a size larger than the display area DA and smaller than the substrate 110. Accordingly, the counter electrode 117 can be placed in the non-display area NDA (or the part of the non-display area NDA) and the display area DA.

The counter electrode 117 according to one example may include a metal material. The counter electrode 117 may reflect the light emitted from the organic light emitting layer 116 in the plurality of subpixels SP toward a lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the light emitting layer 122 toward the substrate 110, and thus the counter electrode 117 may be made of a metal material having high reflectance. The counter electrode 117 according to one example may be formed of a metal material having high reflectance such as a silver (Ag), na aluminum (Al), a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The counter electrode 117 may also be expressed as terms such as a cathode electrode or a reflective electrode.

The encapsulation layer 118 is formed on the counter electrode 117. The encapsulation layer 118 serves to prevent oxygen or moisture from penetrating into the organic light emitting layer 116 and the counter electrode 117. The encapsulation layer 118 can comprise a plurality of layers including at least one inorganic film and at least one organic film. The encapsulation layer 118 may further contain an absorbent material for absorbing moisture or oxygen to enhance the moisture-proofing effect. For example, the absorbent material may be a getter.

On the other hand, as shown in FIG. 3, the encapsulation layer 118 can be disposed not only in the light emission area EA but also in the non-light emission area NEA. The encapsulation layer 118 can be disposed between the counter electrode 117 and the opposing substrate 200. As a result, the opposing substrate 200 can be placed facing the substrate 110 with the pixel electrode 114 (or counter electrode 117) therebetween.

Referring again to FIG. 3, in the display apparatus 100 according to one embodiment of the present disclosure, the low-resistance wiring LRL may not overlap with the light emission area EA. Here, the fact that the low-resistance wiring LRL does not overlap with the light emission area EA may mean that the low-resistance wiring LRL does not completely overlap with the light emission area EA, but is not limited thereto, and may mean that the overlap between the low-resistance wiring LRL and the light emission area EA is minimized.

For example, the low-resistance wiring LRL may not overlap with the light emission area EA by performing the photo process and the etching process using the bank 115 as a mask. Alternatively, the low-resistance wiring LRL may be formed by performing the photo process and the etching process using the bank 115 as a mask, thereby minimizing the overlap with the light emission area EA. By forming the low-resistance wiring LRL using the bank 115 as a mask, a part (or an end) of the low-resistance wiring LRL may be formed adjacent to the light emission area EA.

Therefore, the display apparatus 100 according to one embodiment of the present disclosure may have a structural feature in which a low-resistance wiring LRL contacts the organic light-emitting layer 116 between the pixel electrode 114 and the bank 115.

However, the present disclosure is not necessarily limited thereto, and when a curing process of the bank 115 is performed after an etching process for the low-resistance wiring LRL, the bank 115 may be provided to cover the end of the low-resistance wiring LRL.

Although FIG. 3 illustrates that the low-resistance wiring LRL contacts the organic light-emitting layer 116 only on a right side of the light emission area EA, the low-resistance wiring LRL may be provided to contact the organic light-emitting layer 116 on both sides of the light emission area EA based on FIG. 3. When the photo process and the etching process are performed using the bank 115 as a mask while the low-resistance wiring LRL covers an entire upper surface of the pixel electrode 114, the low-resistance wiring LRL may be provided to contact the organic light-emitting layer 116 on the left and right sides of the light emission area EA based on FIG. 3.

Meanwhile, as described above, the low-resistance wiring LRL may include a metal material having a lower resistance than the pixel electrode 114. For example, the low-resistance wiring LRL may include at least one metal material among Ti, Ni, Zr, Ba, Sr, Ca, and Mg. Such a metal material not only has a lower resistance than the pixel electrode 114, but can also capture oxygen. That is, the metal material forming the low-resistance wiring LRL may be a metal material having a low-resistance characteristic and a strong affinity for oxygen O.

FIG. 4 is a schematic cross-sectional view of part A shown in FIG. 3, and is a drawing explaining oxygen capture of low-resistance wiring.

Referring to FIG. 4, when a pixel electrode 114 including ITO is deposited on a drain electrode 112d including IZO as shown in a left drawing, the oxygen O component may increase inside the pixel electrode 114. However, when a low-resistance wiring LRL is deposited on the upper surface of the pixel electrode 114 as shown in a right drawing, the oxygen O component inside the pixel electrode 114 may be captured (or absorbed) by the low-resistance wiring LRL. This is because the metal material included in the low-resistance wiring LRL has a strong affinity for oxygen O. Accordingly, the oxygen O component inside the pixel electrode 114 can move to the low resistance wiring LRL and be captured inside the low resistance wiring LRL.

Therefore, in the display apparatus 100 according to one embodiment of the present disclosure, the oxidation reaction of the drain electrode 112d in contact with the pixel electrode 114 can be reduced due to a decrease in the oxygen O component inside the pixel electrode 114, so that the lifespan of the thin film transistor 112 can be improved.

Meanwhile, the display apparatus 100 according to one embodiment of the present disclosure may be provided so that, when the low-resistance wiring LRL includes MoTi, the low-resistance wiring LRL is not disposed between the organic light-emitting layer 116 and the pixel electrode 114. This is because MoTi has a low work function with the organic light-emitting layer 116, so that the light-emitting efficiency may be reduced. Therefore, the display apparatus 100 according to one embodiment of the present disclosure may have a structural feature in which the low-resistance wiring LRL is disposed so as not to overlap between the organic light-emitting layer 116 and the pixel electrode 114.

In addition, in the bottom emission method, when a low resistance wiring LRL including a metal material is placed between the organic light emitting layer 116 and the pixel electrode 114, the transmittance of light emitted from the organic light emitting layer 116 passing through the low resistance wiring LRL is low, so the light efficiency may be reduced.

Therefore, the display apparatus 100 according to one embodiment of the present disclosure is provided so that a low resistance wiring LRL is not arranged between the organic light-emitting layer 116 and the pixel electrode 114, so that the light efficiency of light emitted from the organic light-emitting layer 116 and emitted to the outside through the substrate 110 can be improved.

Referring again to FIG. 3, in the display apparatus 100 according to one embodiment of the present disclosure, the low-resistance wiring LRL may be formed to cover the thin film transistor 112. Accordingly, the low-resistance wiring LRL may cover the gate electrode 112b, the source electrode 112c, and the drain electrode 112d of the thin film transistor 112. In other words, the low-resistance wiring LRL may overlap the gate electrode 112b, the source electrode 112c, and the drain electrode 112d of the thin film transistor 112.

Meanwhile, as shown in FIG. 3, a low-resistance wiring LRL may be placed on the pixel electrode 114 in the non-light emission area NEA. Accordingly, the low-resistance wiring LRL may be electrically connected to the light-shielding layer LS through the pixel electrode 114. In addition, as shown in FIG. 3, the low-resistance wiring LRL may have a structural feature that covers a side surface of the active layer 112a.

In a display apparatus 100 according to one embodiment of the present disclosure, a low-resistance wiring LRL may partially overlap with the color filter CF. Since the low-resistance wiring LRL is patterned (or etched) using the bank 115 as a mask, it may be formed adjacent to the light emission area EA. Accordingly, a portion of the low-resistance wiring LRL adjacent to the light emission area EA (or a portion of the low-resistance wiring LRL in contact with the organic light-emitting layer 116) may overlap with the color filter CF.

Consequently, the display apparatus 100 according to one embodiment of the present disclosure may have a structural feature in which a low resistance wiring LRL partially overlaps the color filter CF while covering the circuit area CA including the thin film transistor 112.

Meanwhile, as shown in FIG. 3, the low-resistance wiring LRL may be formed only on a part of the pixel electrode 114. Therefore, an area of the low-resistance wiring LRL may be provided to be smaller than an area of the pixel electrode 114. In contrast, the low-resistance wiring LRL may be provided to cover the thin film transistor 112. Therefore, the area of the low-resistance wiring LRL may be provided to be larger than an area of the circuit area CA in which the thin film transistor 112 is provided. Therefore, the display apparatus 100 according to one embodiment of the present disclosure may have a structural feature in which the area of the low resistance wiring LRL is smaller than the area of the pixel electrode 114 and larger than the area of the circuit area CA.

FIG. 5 is a schematic cross-sectional view of part B shown in FIG. 3.

Referring to FIG. 5, in the display apparatus 100 according to one embodiment of the present disclosure, a side surface 115a of the bank 115 may be arranged in a straight line with a side surface LRLa of a low-resistance wiring LRL.

The low-resistance wiring LRL can be formed by performing a photo process and an etching process using the patterned bank 115 as a mask after a pattern process is performed on the bank 115. Therefore, as shown in FIG. 5, the side surface LRLa of the low-resistance wiring LRL can be arranged in a straight line with the side surface 115a of the bank 115. Therefore, the side surface LRLa of the low-resistance wiring LRL can be in direct contact with the organic light-emitting layer 116 formed in a subsequent process. In this case, the side surface LRLa (or one end) of the low-resistance wiring LRL can have a structure that protrudes further toward the center of the light emission area EA than the bank 115.

In FIG. 5, the side surface LRLa of the low-resistance wiring (LRLa) is described as being arranged in a straight line with the side surface 115a of the bank 115, but it is not necessarily limited thereto. Depending on the degree to which the low-resistance wiring LRL is etched using the bank 115 as a mask, the low-resistance wiring LRL may be arranged only on the lower surface of the bank 115 in the third direction (Z-axis direction) or may be formed by etching further inward than the lower surface of the bank 115. In this case, based on FIG. 5, the side surface LRLa of the low-resistance wiring (LRL) may be arranged to a right of the side surface 115a of the bank 115.

Meanwhile, in the display apparatus 100 according to one embodiment of the present disclosure, the pixel electrode 114 in contact with the drain electrode 112d may be provided with a material different from that of the gate electrode 112b.

In order to improve (or reduce) the resistance of a pixel electrode, a general display apparatus forms a bridge electrode made of the same material as the gate electrode between the pixel electrode and the drain electrode when forming the gate electrode. Since this bridge electrode is made of the same material as the gate electrode and is arranged on the same layer, a process margin (or photo margin) between the electrodes of the same type is essential. Therefore, in the general display apparatus, the bridge electrode in contact with the drain electrode is made of the same material as the gate electrode, and the size of the circuit area cannot but increase due to the process margin (or photo margin) between the gate electrode and the bridge electrode.

In contrast, in the display apparatus 100 according to one embodiment of the present disclosure, since the low resistance wiring LRL is disposed on the upper surface of the pixel electrode 114, the pixel electrode 114 can be in direct contact with the drain electrode 112d. Accordingly, in the display apparatus 100 according to one embodiment of the present disclosure, the pixel electrode 114 in contact with the drain electrode 112d and the gate electrode 112b can be formed of different materials, and a process margin (or photo margin) between the pixel electrode 114 in contact with the drain electrode 112d and the gate electrode 112b may not be required. Accordingly, the display apparatus 100 according to one embodiment of the present disclosure may have a smaller circuit area CA than a general display apparatus, and thus the size (or area) of the light emission area EA may be relatively expanded, thereby improving light efficiency.

For example, in the display apparatus 100 according to one embodiment of the present disclosure, the pixel electrode 114 in contact with the drain electrode 112d may be formed of ITO, and the gate electrode 112b may be formed of a structure in which Cu is laminated on MoTi (or Cu/MoTi). However, the present disclosure is not necessarily limited thereto, and if the pixel electrode 114 in contact with the drain electrode 112d and the gate electrode 112b are different materials, they may be formed of a material other than ITO and Cu/MoTi.

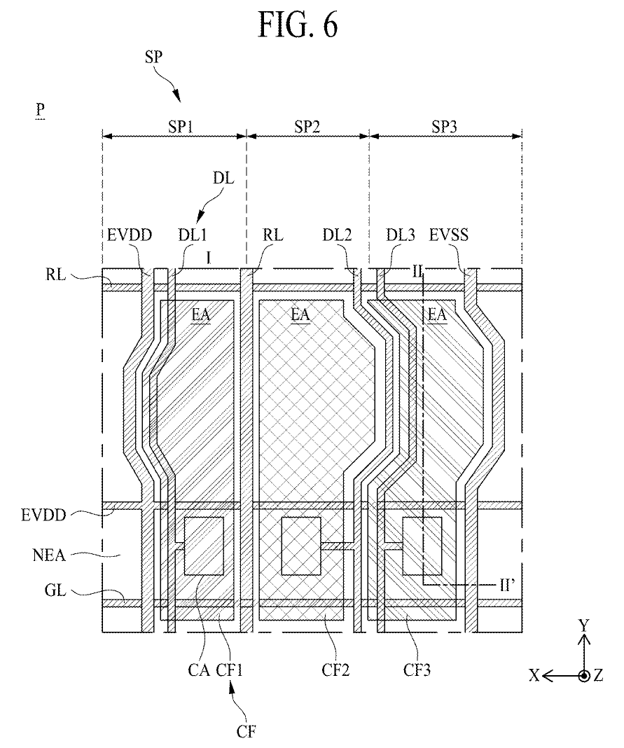

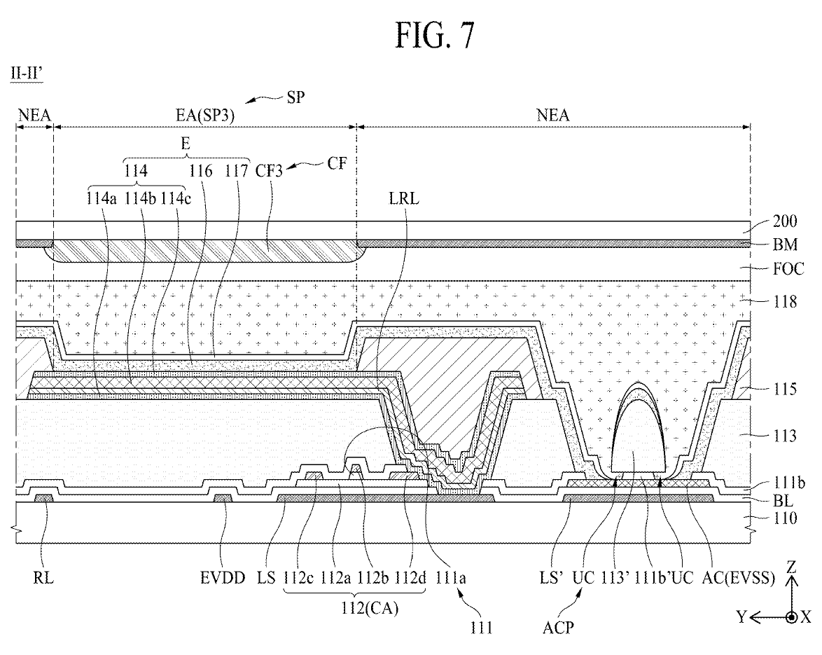

FIG. 6 is a schematic plan view of a display apparatus according to a second embodiment of the present disclosure, and FIG. 7 is a schematic cross-sectional view taken along a line Ⅱ-Ⅱ’ illustrated in FIG. 6.

Referring to FIGS. 6 and 7, the display apparatus 100 according to the second embodiment of the present disclosure is the same as the display apparatus according to FIG. 1 described above, except that the positions of the wires (or the overlapping positions with the light emission area EA) and the positions of the color filters CF are changed as the top emission method is changed, and a common power wire EVSS, a black matrix BM, and an upper organic film FOC are added. Therefore, the same reference numerals are given to the same configurations, and only different configurations will be described below.

In the case of the display apparatus according to FIG. 1, since it is a bottom emission method, the circuit area CA does not overlap with the light emission area EA and is arranged adjacent to the light emission area EA. In addition, in the case of the display apparatus according to FIG. 1, the low resistance wiring LRL, pixel power wiring EVDD, data wiring DL, and reference wiring RL are arranged so as not to overlap with the light emission area EA. When the low-resistance wiring LRL, pixel power wiring EVDD, data wiring DL, and reference wiring RL overlap the light emission area EA, the light emitted from the light emission area EA is blocked (or interfered) by the low-resistance wiring LRL, pixel power wiring EVDD, data wiring DL, and reference wiring RL and cannot be emitted to the outside of the substrate 110, thereby reducing light efficiency.

In contrast, in the case of the display apparatus according to FIG. 6, since it is a top emission method, the circuit area CA can be provided with a structure in which it overlaps a part of the light emission area EA. That is, in the case of the display apparatus according to FIG. 6, since the light emitted from the light emission area EA is emitted outward through the opposing substrate 200, even if all or part of the circuit area CA overlaps the light emission area EA, it does not affect the light efficiency. Accordingly, the display apparatus 100 according to FIG. 6 may have a structural feature in which the circuit area CA overlaps a portion of the light emission area EA.

In addition, in the case of the display apparatus according to FIG. 6, since it is a top emission method, even if at least a portion of each of the pixel power wiring EVDD, the data wirings DL, and the reference wiring RL overlaps the light emission area EA, it may not affect the light efficiency. This is because each of the pixel power wiring EVDD, the data wirings DL, and the reference wiring RL is arranged closer to the substrate 110 than the organic light emitting element E. Accordingly, the display apparatus 100 according to FIG. 6 may have a structural feature in which at least a portion of each of the pixel power wiring EVDD, data wirings DL, and reference wiring RL overlaps the light emission area EA.

In addition, since the display apparatus 100 according to FIG. 6 is a top emission method, even if at least a part of the low resistance wiring LRL overlaps the light emission area EA, the light efficiency may not be affected. As shown in FIG. 7, the display apparatus 100 according to the second embodiment of the present disclosure includes the pixel electrode 114 including a first pixel electrode 114a, a second pixel electrode 114b, and a third pixel electrode 114c, and the second pixel electrode 114b and the third pixel electrode 114c are arranged on the low resistance wiring LRL. That is, the display apparatus 100 according to the second embodiment of the present disclosure may have a structural feature in which a low resistance wiring LRL is located inside the pixel electrode 114.

Therefore, in the display apparatus 100 according to the second embodiment of the present disclosure, since an electric field can be formed between the third pixel electrode 114c and the counter electrode 117 on the low-resistance wiring LRL, the low-resistance wiring LRL may not affect the light-emitting efficiency, and thus the low-resistance wiring LRL may be provided to partially overlap the light emission area EA and the circuit area CA.

Meanwhile, in the case of the display apparatus according to FIG. 1, since it is a bottom emission method, the color filter CF is placed between the planarization layer 113 and the substrate 110. In contrast, in the case of the display apparatus 100 according to the second embodiment of the present disclosure, since it is a top emission method, the color filter CF can be placed between the encapsulation layer 118(or upper organic film FOC) and the opposing substrate 200.

Referring to FIG. 7, the display apparatus 100 according to the second embodiment of the present disclosure may further include a black matrix BM and an upper organic film FOC.

The black matrix BM is to prevent color mixing and/or light leakage between a plurality of subpixels SP1, SP2, SP3. The black matrix BM may be formed of a black-based material. An area where the black matrix BM and/or the bank 115 is provided may be a dead zone or a non-luminous area. According to one example, the black matrix BM is formed on the opposing substrate 200 so as to overlap at least a portion of the bank 115, thereby reducing a cell gap between the organic light-emitting layer 116 and the opposing substrate 200, thereby preventing color mixing between the subpixels SP.

The upper organic film FOC may be placed between the encapsulation layer 118 and at least one color filter CF (or black matrix BM). The upper organic film FOC may be provided on the front surface of the opposing substrate 200 so as to cover at least one color filter CF and the black matrix BM. The upper organic film FOC serves to prevent oxygen or moisture from penetrating into the organic light-emitting layer 116 and the counter electrode 117.

Referring again to FIG. 7, in the display apparatus 100 according to the second embodiment of the present disclosure, the pixel electrode 114 may include a first pixel electrode 114a, a second pixel electrode 114b, and a third pixel electrode 114c.

According to one example, the first pixel electrode 114a may be in contact with a lower surface of the low-resistance wiring LRL. Therefore, the first pixel electrode 114a may be partially disposed between the low-resistance wiring LRL and the planarization layer 113.

The first pixel electrode 114a may partially overlap the light emission area EA and the circuit area CA. As shown in FIG. 7, the first pixel electrode 114a may extend from the light emission area EA to the non-light emission area NEA (or the circuit area CA) and may contact the drain electrode 112d of the thin film transistor 112. The first pixel electrode 114a may include a transparent conductive material. For example, the first pixel electrode 114a may include ITO.

According to one example, the second pixel electrode 114b may be in contact with an upper surface of the low-resistance wiring LRL. Therefore, the second pixel electrode 114b may be partially disposed between the low-resistance wiring LRL and the third pixel electrode 114c.

The second pixel electrode 114b is intended to reflect light emitted from the organic light-emitting layer 116 toward the substrate 110 toward the opposing substrate 200. Therefore, the second pixel electrode 114b may include a metal material having high reflectivity. For example, the second pixel electrode 114b may include Ag.

The second pixel electrode 114b may partially overlap the light emission area EA and the circuit area CA. As shown in FIG. 7, the second pixel electrode 114b may be disposed to extend from the light emission area EA to the non-light emission area NEA (or the circuit area CA).

According to one example, the third pixel electrode 114c may be in contact with an upper surface of the second pixel electrode 114b. Therefore, the third pixel electrode 114c may be partially disposed between the second pixel electrode 114b and the organic light-emitting layer 116.

The third pixel electrode 114c may partially overlap the light emission area EA and the circuit area CA. As shown in FIG. 7, the third pixel electrode 114c may be arranged to extend from the light emission area EA to the non-light emission area NEA (or the circuit area CA). The third pixel electrode 114c may include a transparent conductive material. For example, the third pixel electrode 114c may include ITO.

Therefore, the display apparatus 100 according to the second embodiment of the present disclosure may be provided with a quadruple film in which layers forming the low-resistance wiring LRL and the pixel electrode 114 in the light emission area EA are combined, and may also have a structural feature in which layers forming the low-resistance wiring LRL and the pixel electrode 114 on the drain electrode 112d of the thin film transistor 112 are combined with a quadruple film.

Therefore, the display apparatus 100 according to the second embodiment of the present disclosure can have improved light efficiency through the quadruple film structure of the light emission area EA, and the lifespan of the thin film transistor 112 can be improved through the quadruple film structure on the drain electrode 112d of the thin film transistor 112.

In addition, since the display apparatus 100 according to the second embodiment of the present disclosure can improve light efficiency through the quadruple-layer structure of the light emission area EA, it can have the same light-emitting efficiency or improve the light-emitting efficiency to a greater extent than a display apparatus that does not have a pixel electrode (e.g., the second pixel electrode 114b) including Ag in the light emission area EA even with low power consumption, so that the overall power consumption can be reduced.

Meanwhile, the display apparatus 100 according to the second embodiment of the present disclosure may have a structural feature in which the layers forming the low-resistance wiring LRL and the pixel electrode 114 are combined as a quadruple layer on the drain electrode 112d of the thin film transistor 112, so that the first pixel electrode 114a, the second pixel electrode 114b, the third pixel electrode 114c, and the low-resistance wiring LRL partially overlap at least a portion of the thin film transistor 112.

Referring again to FIG. 7, the display apparatus 100 according to the second embodiment of the present disclosure may further include an auxiliary electrode contact portion ACP.

The auxiliary electrode contact portion ACP is for additionally applying a common voltage to each of the plurality of pixels P. Therefore, each of the plurality of auxiliary electrode contact portions ACP may be included in each of the plurality of pixels P. Each of the plurality of auxiliary electrode contact portions ACP may be arranged in a non-light emission area NEA adjacent to the light emission area EA. For example, the auxiliary electrode contact portion ACP may be arranged in a non-light emission area NEA adjacent to the light emission area EA of the third sub-pixel SP3.

The auxiliary electrode contact portion ACP may include an auxiliary electrode AC. For example, the auxiliary electrode AC may be a common power wiring EVSS of FIG. 6. According to one example, the common power wiring EVSS is for applying a common voltage to the display area DA (or a plurality of pixels P), and may be arranged in a right non-light emission area NEA of the third sub-pixel SP based on FIG. 6. The auxiliary electrode contact portion ACP is provided so that the auxiliary electrode AC and the counter electrode 117 are in contact, thereby additionally applying a common voltage to each of the plurality of pixels P.

As shown in FIG. 7, an auxiliary light-shielding layer LS’ may be further disposed under the auxiliary electrode AC of the auxiliary electrode contact portion ACP in the same layer as the light-shielding layer LS. The auxiliary light-shielding layer LS’ is intended to block or reduce external light reflectance by the auxiliary electrode AC. Therefore, the auxiliary light-shielding layer LS’ may be provided with a wider width than the auxiliary electrode AC.

Referring to FIG. 7, in the display apparatus 100 according to the second embodiment of the present disclosure, the auxiliary electrode contact portion ACP may further include a plurality of undercut portions UC.

The plurality of undercut portions UC are intended to disconnect the organic light-emitting layer 116. The plurality of undercut portions UC may refer to a plurality of spaces formed between the auxiliary electrode AC and the island-shaped planarization layer 113’. The island-shaped planarization layer 113’ may be arranged to be spaced apart from the auxiliary electrode AC in the third direction (Z-axis direction). For example, since an island-shaped passivation layer 111b’ can be arranged on the auxiliary electrode AC, the island-shaped planarization layer 113’ can be arranged spaced apart from the auxiliary electrode AC in the third direction (Z-axis direction).

According to one example, the auxiliary electrode AC may be formed together with the gate electrode 112b of the thin film transistor 112. Therefore, the auxiliary electrode AC may be formed in the same layer as the gate electrode 112b using the same material. For example, the auxiliary electrode AC may be formed of a conductive material such as IZO and may be positioned between the passivation layer 111b and the buffer layer BL.

Therefore, in the display apparatus 100 according to the second embodiment of the present disclosure, the counter electrode 117 can be brought into contact with the auxiliary electrode AC at the undercut portion UC of the auxiliary electrode contact portion ACP, and thus, each of the plurality of pixels P can additionally receive a common voltage from the auxiliary electrode AC.

In the case of a general large-area display apparatus, a voltage drop may occur when a common voltage supplied from an edge portion of the display panel is applied to a center portion of the display panel. Therefore, a general display apparatus has a problem in that the brightness of the image emitted from the edge portion and the center portion of the display panel is uneven. In addition, general display apparatuses have the problem of increasing overall power consumption because they must drive the display panel with high power to solve the problem of uneven brightness of the image as above.

However, the display apparatus 100 according to the second embodiment of the present disclosure is provided such that the auxiliary electrode AC is arranged to overlap the non-light emission area NEA included in each of the plurality of pixels P, and the counter electrode 117 of each of the plurality of pixels P is in contact with the auxiliary electrode AC, so that the counter electrode 117 can receive a common voltage through the auxiliary electrode AC even in a central portion of a display panel. Accordingly, the display apparatus 100 according to the second embodiment of the present disclosure is provided so that the common voltage difference between the edge portion and the center portion of the display panel is small or does not occur, so that the brightness of the image emitted from the edge portion and the center portion of the display panel can be provided uniformly.

In addition, the display apparatus 100 according to the second embodiment of the present disclosure is provided such that the counter electrode 117 and the auxiliary electrode AC are in contact at the undercut portion UC in the auxiliary electrode contact portion ACP, so that voltage drop in the center portion of the display panel can be prevented, and thus the brightness of the edge portion and the center portion of the display panel can be made uniform with low power, so that power consumption reduction can be maximized.

Meanwhile, as shown in FIG. 7, an island-shaped organic light-emitting layer 116 and an island-shaped counter electrode 117 may be arranged on the island-shaped planarization layer 113’. This is because each of the organic light-emitting layer 116 and the counter electrode 117 is disconnected by the undercut portion UC of the auxiliary electrode contact portion ACP.

Consequently, the display apparatus 100 according to the second embodiment of the present disclosure may have a structural feature in which the counter electrode 117 is partially in contact with the auxiliary electrode AC at the auxiliary electrode contact portion ACP.

In addition, the display apparatus 100 according to the second embodiment of the present disclosure may have a structural feature in which the organic light-emitting layer 116 is disconnected by the auxiliary electrode contact portion ACP (or the undercut portion UC). The display apparatus 100 according to the second embodiment of the present disclosure is provided such that the organic light-emitting layer 116 is disconnected by the auxiliary electrode contact portion ACP (or an undercut portion UC), thereby preventing or reducing moisture penetration through the organic light-emitting layer 116.

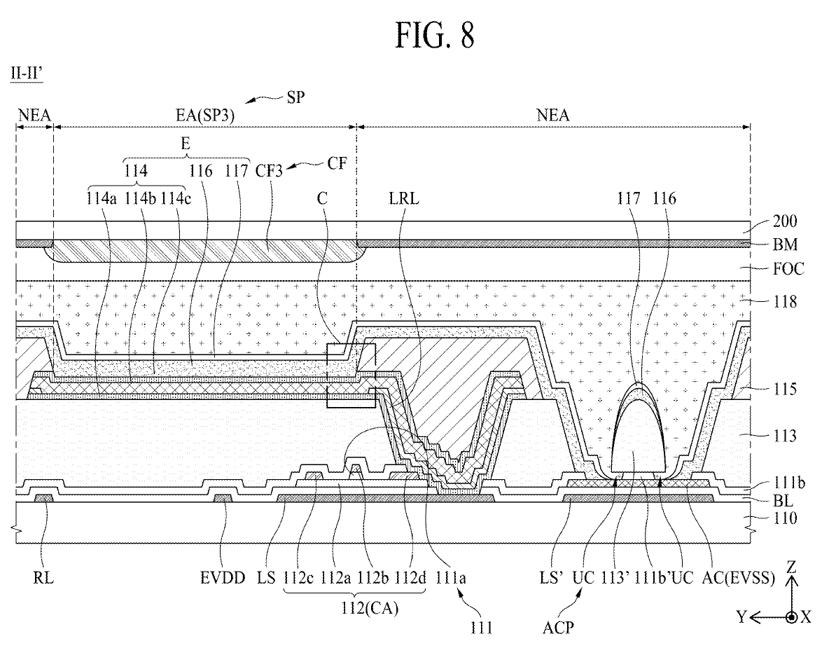

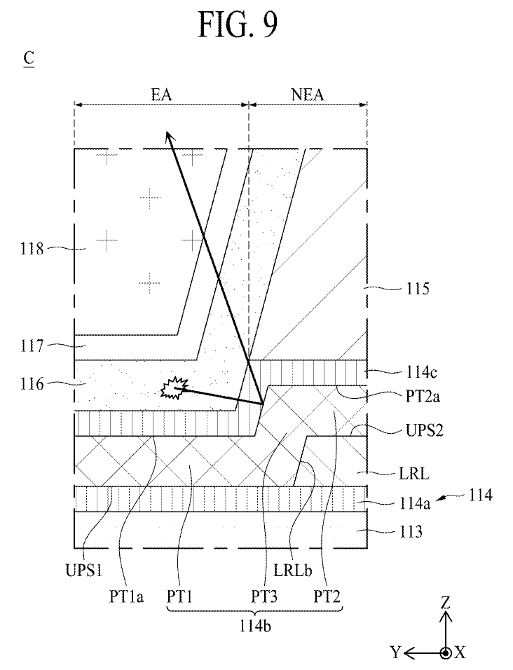

FIG. 8 is a schematic cross-sectional view of a display apparatus according to a third embodiment of the present disclosure, and FIG. 9 is a schematic cross-sectional view of part C illustrated in FIG. 3.

Referring to FIGS. 8 and 9, the display apparatus 100 according to the third embodiment of the present disclosure is identical to the display apparatus according to FIG. 6 described above, except that the low-resistance wiring LRL is positioned so as not to overlap the light emission area EA. Therefore, the same reference numerals are assigned to the same configurations, and only different configurations will be described below.

In the case of the display apparatus according to FIG. 6, since it is a top emission method, even if at least a part of the low resistance wiring LRL overlaps the light emission area EA, the light efficiency may not be affected. Accordingly, the display apparatus according to FIG. 6 may be provided such that the low resistance wiring LRL is positioned inside the pixel electrode 114, and a part of the low resistance wiring LRL overlaps the light emission area EA.

In contrast, in the case of the display apparatus according to FIG. 8, the low-resistance wiring LRL may be provided so as not to overlap the light emission area EA. The low-resistance wiring LRL may not overlap the light emission area EA by being fully deposited on the first pixel electrode 114a and then removing a portion corresponding to the light emission area EA through a photo process and an etching process.

Accordingly, the display apparatus 100 according to FIG. 8 may have a structural feature in which the layers forming the pixel electrode 114 in the light-emission area EA may be provided as a triple layer, and the layers forming the pixel electrode 114 and the low-resistance wiring LRL on the drain electrode 112d of the thin film transistor 112 may be provided as a combined quadruple layer.

In addition, the display apparatus 100 according to FIG. 8 may be provided so that the low-resistance wiring LRL does not overlap the light emission area EA, so that the first pixel electrode 114a can partially contact the lower surface of the low-resistance wiring LRL, and the second pixel electrode 114b can be provided so that the upper surface of the first pixel electrode 114a in the light emission area EA.

Therefore, as shown in FIG. 8, the display apparatus 100 according to the third embodiment of the present disclosure may have the second pixel electrode 114b with a step equal to a thickness of the low-resistance wiring LRL in the non-light emission area NEA adjacent to the light emission area EA. The second pixel electrode 114b may have a step by being formed along the profiles of the first pixel electrode 114a overlapping the light emission area EA and the low-resistance wiring LRL overlapping the non-light emission area NEA, respectively.

Referring to FIG. 9, the second pixel electrode 114b may include a first portion PT1, a second portion PT2, and a third portion PT3.

According to one example, the first portion PT1 may be in contact with an upper surface of the first pixel electrode 114a. For example, the first portion PT1 may be a part of the second pixel electrode 114b partially overlapping the light emission area EA. As shown in FIG. 9, the first portion PT1 may be arranged parallel to the first direction (Y-axis direction). Accordingly, the first portion PT1 may be arranged parallel to an upper surface of the substrate 110.

According to one example, the second portion PT2 may be in contact with an upper surface of the low-resistance wiring LRL. For example, the second portion PT2 may be in contact with the upper surface of the low-resistance wiring LRL arranged in the non-light emission area NEA. As shown in FIG. 9, the second portion PT2 may be arranged parallel to the first direction (Y-axis direction).

According to one example, the third portion PT3 can connect the first portion PT1 and the second portion PT2. Therefore, as shown in FIG. 9, the third portion PT3 can be in contact with a side surface of the low-resistance wiring LRL. As the side surface of the low-resistance wiring LRL is formed to be inclined with respect to the upper surface of the substrate 110, the third portion PT3 can be arranged to be inclined with respect to the upper surface of the substrate 110.

Referring to FIG. 9, the display apparatus 100 according to the third embodiment of the present disclosure is provided so that the low-resistance wiring LRL does not overlap the light emission area EA, so that the second pixel electrode 114b can contact the upper surface of the first pixel electrode 114a in the light emission area EA and can contact the side surface and the upper surface of the low-resistance wiring LRL in the non-light emission area NEA. Therefore, the display apparatus 100 according to the third embodiment of the present disclosure may have a structural feature in which an upper surface PT1a of the first portion PT1 is arranged closer to the substrate 110 than an upper surface PT2a of the second portion PT2.

Meanwhile, the display apparatus 100 according to the third embodiment of the present disclosure can reflect some of the light emitted from the organic light-emitting layer 116 by having the third portion PT3 inclined relative to the upper surface of the substrate 110. As described above, the second pixel electrode 114b is provided to include a metal material (e.g., Ag) having a high reflectivity, thereby being able to reflect some of the light emitted from the organic light-emitting layer 116.

Therefore, in the display apparatus 100 according to the third embodiment of the present disclosure, some of the light emitted from the organic light-emitting layer 116 can be reflected by the third portion PT3 and emitted to the outside through the opposing substrate 200, so that the improvement in light efficiency can be maximized.

Further embodiments of the present disclosure are described below.

A display apparatus 100 may include a substrate 110 and a thin film transistor 112 disposed on the substrate 110. The thin film transistor 112 may include a first electrode and a second electrode. A light emitting element E may be provided and may include a pixel electrode 114 extending toward the thin film transistor and electrically connected to the first electrode of the thin film transistor. A wiring LRL may be disposed in contact with the pixel electrode 114 and may partially overlap at least a portion of the thin film transistor in a plan view. The wiring LRL may have a lower resistance than the pixel electrode 114.

In some embodiments, the wiring LRL may include a metal material having a higher affinity for oxygen than a material of the pixel electrode 114. The oxygen affinity of the wiring material may be selected relative to the pixel electrode material such that oxygen present in the pixel electrode tends to migrate toward the wiring.

In certain embodiments, the wiring LRL may include at least one material selected from Ti, Ni, Zr, Ba, Sr, Ca, and Mg. The wiring may be formed of a single material or a combination of materials from this group.

The pixel electrode 114 may be formed as a multilayer structure. The multilayer structure may include a first pixel electrode 114a comprising a transparent conductive material, a second pixel electrode 114b comprising a reflective metal material, and a third pixel electrode 114c comprising a transparent conductive material. The wiring LRL may be disposed on the first pixel electrode, and the first pixel electrode, the wiring, the second pixel electrode, and the third pixel electrode may partially overlap at least a portion of the thin film transistor.

The light emitting element E may further include a counter electrode 117 and a light emitting layer 116 disposed between the counter electrode 117 and the pixel electrode 114. The third pixel electrode 114c may be disposed between the second pixel electrode 114b and the light emitting layer 116.

An auxiliary electrode contact portion ACP may be provided and may include an auxiliary electrode AC and at least one undercut portion UC. The light emitting layer 116 may be disconnected at the undercut portion so as to form a barrier against moisture penetration.

In some embodiments, the light emitting element E may include a counter electrode and a light emitting layer between the counter electrode and the pixel electrode, and the counter electrode may contact the auxiliary electrode at the undercut portion so as to receive a common voltage.

A bank 115 may be provided covering at least a portion of the pixel electrode. A side surface LRLa of the wiring may be aligned with a side surface 115a of the bank 115. In certain embodiments, the side surface of the wiring may be aligned in a straight line with the side surface of the bank (see FIG. 5).

An opposing substrate 200 may be disposed to face the substrate 110. The wiring may have an inclined side surface (e.g., LRLa, LRLb). The second pixel electrode 114b may include a first portion PT1 contacting an upper surface UPS1 of the first pixel electrode 114a, a second portion PT2 contacting an upper surface UPS2 of the wiring LRL, and a third portion PT3 connecting the first portion and the second portion. The third portion PT3 may be inclined relative to the substrate and may contact the inclined side surface LRLb of the wiring LRL so as to reflect light toward the opposing substrate 200.

An auxiliary electrode contact portion ACP may be disposed in a non light emission area NEA and may include an auxiliary electrode AC and an island shaped planarization layer 113’ spaced apart from the auxiliary electrode to define an undercut portion. The light emitting layer may be physically disconnected at the undercut portion to form a barrier against moisture penetration.

The light emitting element E may be disposed in a light emission area EA. The thin film transistor may include a source electrode, a drain electrode, and a gate electrode. The gate electrode may be formed of a material different from the pixel electrode. The pixel electrode may be in direct contact with the drain electrode without an intervening bridge electrode so that the light emission area is expanded relative to a circuit area occupied by the thin film transistor.

Embodiments of the present disclosure have been described in more detail with reference to the accompanying drawings, but the present disclosure is not necessarily limited to these embodiments and may be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this disclosure should be construed to be included within the scope of the claims of this disclosure.

The display apparatus according to the present disclosure is provided such that a low-resistance wiring is in contact with a pixel electrode that is in contact (or connected) with a thin film transistor, so that the resistance of the pixel electrode can be improved (or reduced).

The display apparatus according to the present disclosure can improve the lifespan of a thin film transistor by having a low-resistance wiring including a metal that captures oxygen.

In the display apparatus according to the present disclosure, the gate electrode and pixel electrode of a thin film transistor are made of different materials, so that the size (or area) of the light emission area can be expanded.

The display apparatus according to the present disclosure is provided so that a portion of the light emitted from an organic light-emitting layer is reflected and emitted by a second pixel electrode, thereby improving light efficiency.

Since the display apparatus according to the present disclosure can have improved light efficiency by the second pixel electrode, the display apparatus can have the same light efficiency or have improved light efficiency more than that of a display apparatus without a second pixel electrode even with lower power consumption, so that the overall power consumption can be reduced.

The effects to be obtained from the present disclosure are not limited to those mentioned above, and other effects not mentioned will be apparent to one of ordinary skill in the art from the description.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a plurality of pixels having a plurality of subpixels;
a thin film transistor provided on the substrate and provided in each of the plurality of subpixels;
a pixel electrode connected to the thin film transistor; and
a low-resistance wiring in contact with the pixel electrode,
wherein the low-resistance wiring partially overlaps at least a portion of the thin film transistor.

2. The display apparatus of claim 1, wherein the low-resistance wiring includes a metal material having an affinity for oxygen.

3. The display apparatus of claim 2, wherein the metal material that captures the oxygen is at least one of Ti, Ni, Zr, Ba, Sr, Ca, and Mg.

4. The display apparatus of claim 1, wherein the thin film transistor includes a source electrode, a drain electrode disposed spaced apart from the source electrode, and a gate electrode disposed between the source electrode and the drain electrode, and the pixel electrode in contact with the drain electrode is made of a different material from the gate electrode.

5. The display apparatus of claim 4, wherein the source electrode and the drain electrode include IZO, and the pixel electrode is in contact with the source electrode or the drain electrode, and a portion of the low-resistance wiring overlaps the pixel electrode in contact with the source electrode or the drain electrode.

6. The display apparatus of claim 1, wherein the plurality of subpixels include:
a light emission area in which the pixel electrode is partially arranged; and
a circuit area adjacent to the light emission area and having the thin film transistor, and
wherein the low-resistance wiring does not overlap the light emission area.

7. The display apparatus of claim 6, wherein the low-resistance wiring is in contact with an upper surface of the pixel electrode.

8. The display apparatus of claim 6, wherein the plurality of subpixels further include:
a bank partially covering the pixel electrode; and
an organic light-emitting layer covering the pixel electrode and the bank, and
wherein the low-resistance wiring is in contact with the organic light-emitting layer between the pixel electrode and the bank.

9. The display apparatus of claim 8, wherein a side of the bank is arranged in a straight line with a side of the low-resistance wiring.

10. The display apparatus of claim 1, wherein the plurality of subpixels include:
a light emission area in which the pixel electrode is partially arranged; and
a circuit area overlapping a portion of the light emission area and having the thin film transistor, and
wherein the low-resistance wiring is partially overlapping the light emission area and the circuit area.

11. The display apparatus of claim 10, wherein the pixel electrode is a multilayer structure including:
a first pixel electrode in contact with a lower surface of the low-resistance wiring;
a second pixel electrode in contact with an upper surface of the low-resistance wiring; and
a third pixel electrode in contact with an upper surface of the second pixel electrode.

12. The display apparatus of claim 11, wherein the first pixel electrode and the third pixel electrode include ITO, and the second pixel electrode includes Ag.

13. The display apparatus of claim 11, wherein the first pixel electrode, the second pixel electrode, the third pixel electrode, and the low-resistance wiring partially overlap at least a portion of the thin film transistor.

14. The display apparatus of claim 10, wherein each of the plurality of pixels is arranged in a non-light emission area adjacent to the light emission area and further includes an auxiliary electrode contact portion including an auxiliary electrode.

15. The display apparatus of claim 14, wherein the plurality of subpixels further include:
a bank partially covering the pixel electrode;
an organic light-emitting layer covering the pixel electrode and the bank; and
a counter electrode on the organic light-emitting layer,
wherein the counter electrode is partially in contact with the auxiliary electrode at the auxiliary electrode contact portion.

16. The display apparatus of claim 15, wherein the organic light-emitting layer is disconnected by the auxiliary electrode contact portion.

17. The display apparatus of claim 1, wherein the plurality of subpixels include:
a light emission area in which the pixel electrode is partially arranged; and
a circuit area overlapping a portion of the light emission area and having the thin film transistor, and
wherein the low-resistance wiring does not overlap the light emission area.

18. The display apparatus of claim 17, wherein the pixel electrode is a multilayer structure including:
a first pixel electrode partially in contact with a lower surface of the low-resistance wiring;
a second pixel electrode in contact with an upper surface of the low-resistance wiring; and
a third pixel electrode in contact with an upper surface of the second pixel electrode,
wherein the second pixel electrode is in contact with an upper surface of the first pixel electrode in the light emission area.

19. The display apparatus of claim 18, wherein the second pixel electrode comprises:
a first portion in contact with an upper surface of the first pixel electrode;
a second portion in contact with an upper surface of the low-resistance wiring; and
a third portion connecting the first portion and the second portion,
wherein an upper surface of the first portion is positioned closer to the substrate than an upper surface of the second portion.

20. The display apparatus of claim 19, further comprising an opposing substrate facing the substrate with the pixel electrode interposed therebetween,
wherein the plurality of subpixels further include an organic light-emitting layer disposed on the pixel electrode,
wherein the third portion is disposed at an angle with respect to an upper surface of the substrate, and
wherein a portion of the light emitted from the organic light-emitting layer is reflected by the third portion and emitted to an outside through the opposing substrate.

21. A display apparatus comprising:
a substrate;
a thin film transistor disposed on the substrate, the thin film transistor including a first electrode and a second electrode;
a light emitting element having a pixel electrode, the pixel electrode extending towards the transistor and electrically connected to the first electrode of the thin film transistor; and
a wiring in contact with the pixel electrode and partially overlapping at least a portion of the thin film transistor in a plan view, the wiring having a lower resistance than the pixel electrode.

22. The display apparatus of claim 21, wherein the wiring includes a metal material having a higher affinity for oxygen than a material of the pixel electrode.

23. The display apparatus of claim 21, wherein the wiring includes at least one material selected from the group consisting of Ti, Ni, Zr, Ba, Sr, Ca, and Mg.

24. The display apparatus of claim 21, wherein the pixel electrode is a multilayer structure including:
a first pixel electrode comprising a transparent conductive material;
a second pixel electrode comprising a reflective metal material; and
a third pixel electrode comprising a transparent conductive material,
wherein the wiring is disposed on the first pixel electrode, and
wherein the first pixel electrode, the wiring, the second pixel electrode, and the third pixel electrode partially overlap at least a portion of the thin-film transistor.

25. The display apparatus of claim 24, wherein the light emitting element includes a counter electrode and a light emitting layer between the counter electrode and the pixel electrode, and
wherein the third pixel electrode is disposed between the second pixel electrode and the light emitting layer.

26. The display apparatus of claim 21, further comprising:
an auxiliary electrode contact portion including an auxiliary electrode and at least one undercut portion,
wherein the light emitting layer is disconnected by the undercut portion to form a barrier against moisture penetration.

27. The display apparatus of claim 26, wherein the light emitting element includes a counter electrode and a light emitting layer between the counter electrode and the pixel electrode, and
wherein the counter electrode is in contact with the auxiliary electrode at the undercut portion to receive a common voltage.

28. The display apparatus of claim 21, further comprising a bank covering at least a portion of the pixel electrode, wherein a side surface of the wiring is aligned with a side surface of the bank.

29. The display apparatus of claim 28, wherein the side surface of the wiring is aligned in a straight line with a side surface of the bank.

30. The display apparatus of claim 24, further comprising an opposing substrate disposed to face the substrate,
wherein the wiring has an inclined side surface, and
wherein the second pixel electrode includes:
a first portion in contact with an upper surface of the first pixel electrode;
a second portion in contact with an upper surface of the wiring; and
a third portion connecting the first and second portions, the third portion being inclined relative to the substrate and in contact with the inclined side surface of the wiring to reflect light toward the opposing substrate.

31. The display apparatus of claim 21, further comprising an auxiliary electrode contact portion disposed in a non-light emission area, the auxiliary electrode contact portion comprising:
an auxiliary electrode;
an island-shaped planarization layer spaced apart from the auxiliary electrode to define an undercut portion; and
wherein the light emitting layer is physically disconnected at the undercut portion to form a barrier against moisture penetration.

32. The display apparatus of claim 21, wherein the light emitting element is provided in a light emission area,
wherein the thin film transistor includes a source electrode, a drain electrode and a gate electrode,
wherein the gate electrode is made of a material different from the pixel electrode, and
wherein the pixel electrode is in direct contact with the drain electrode without an intervening bridge electrode, such that a size of the light emission area is expanded relative to a circuit area occupied by the thin film transistor.
